(19) United States
(12) Patent Application Publication
(10) Pub. No.: US 2024/0313162 A1
(43) Pub. Date: Sep. 19, 2024

(54) LIGHT EMITTING ELEMENT, METHOD OF MANUFACTURING LIGHT EMITTING ELEMENT, AND DISPLAY DEVICE

(71) Applicant: Samsung Display Co., LTD., Yongin-si (KR)

(72) Inventors: Sang Ho PARK, Yongin-si (KR); Sang Ho JEON, Yongin-si (KR); Sung Hoon KIM, Yongin-si (KR)

(73) Assignee: Samsung Display Co., LTD., Yongin-si (KR)

(21) Appl. No.: 18/603,318

(22) Filed: Mar. 13, 2024

(30) Foreign Application Priority Data
Mar. 13, 2023 (KR) 10-2023-0032723

(51) Int. Cl. H01L 33/32; H01L 25/075; H01L 33/00; H01L 33/62

(52) U.S. Cl. CPC H01L 33/32; H01L 25/0753; H01L 33/0075; H01L 33/62

(57) ABSTRACT

Provided herein is a light emitting element including a semiconductor stack structure including an N-type semiconductor layer, a P-type semiconductor layer, and an active layer disposed between the N-type semiconductor layer and the P-type semiconductor layer; an intermediate passivation structure disposed on a side surface of the semiconductor stack structure; and an insulating layer disposed on the intermediate passivation structure, and including a metal oxide. The intermediate passivation structure includes a crystal structure including nitrogen (N) and material forming the semiconductor stack structure.

### CROSS-REFERENCE TO RELATED APPLICATION(S)

This application claims priority to and benefits of Korean patent application No. 10-2023-0032723 under 35 U.S.C. § 119, filed on Mar. 13, 2023, in the Korean Intellectual Property Office, the entire contents of which are incorporated herein by reference.

### BACKGROUND

### 1. Technical Field

Various embodiments relate to a light emitting element, a method of manufacturing the light emitting element, and a display device.

### 2. Description of the Related Art

Recently, as interest in information display increases, research and development on display devices have been continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Various embodiments are directed to a light emitting element having a reduced defect rate, a method of manufacturing the light emitting element, and a display device comprising the light emitting element.

Various embodiments are directed to a light emitting element having improved emission efficiency, a method of manufacturing the light emitting element, and a display device comprising the light emitting element.

Various embodiments are directed to a light emitting element, a method of manufacturing the light emitting element, and a device comprising the light emitting element, in which structures of sub-pixels having substantially uniform light efficiency can be implemented by compensating for emission efficiency by colors of light emitting elements.

An embodiment may provide a light emitting element that may include a semiconductor stack structure comprising an N-type semiconductor layer; a P-type semiconductor layer; and an active layer disposed between the N-type semiconductor layer and the P-type semiconductor layer; an intermediate passivation structure formed on a side surface of the semiconductor stack structure; and an insulating layer disposed on the intermediate passivation structure, and comprising a metal oxide. The intermediate passivation structure may comprise a crystal structure comprising nitrogen (N), and a material forming the semiconductor stack structure.

In an embodiment, the semiconductor stack structure may comprise GaP. The intermediate passivation structure may comprise GaPₓN₍₁₋ₓ₎.

In an embodiment, the semiconductor stack structure may comprise InₓAl_{y}Ga_{(1-x-y)}P. The intermediate passivation structure may comprise AlₓIn_{y}Ga_{(1-y)}PzN_{(1-z)}.

In an embodiment, the intermediate passivation structure may space apart an interior of the semiconductor stack structure from the insulating layer. The insulating layer may comprise a metal oxide comprising at least one metal selected from a group comprising tantalum (Ta), hafnium (Hf), zirconium (Zr), lanthanum (La), silicon (Si), titanium (Ti), and aluminum (Al).

In an embodiment, the insulating layer may comprise insulating layers comprising two or more materials different from each other.

In an embodiment, the metal oxide forming the insulating layer may have a bonding energy greater than a bonding energy of the material forming the semiconductor stack structure.

In an embodiment, in a crystal structure of the intermediate passivation structure comprising the GaP, a displacement of P based on a reference position may be determined to be within about 8% compared to a bonding length between Ga and P. The reference position of the P may be a position of the P in the crystal structure of the intermediate passivation structure in case that separate energy is not supplied to the light emitting element.

In an embodiment, the diameter of the light emitting element may be about 100 μm or less.

In an embodiment, the intermediate passivation structure may be an intermediate passivation layer. A first surface of the intermediate passivation layer may contact the semiconductor stack structure, and a second surface of the intermediate passivation layer may contact the insulating layer.

In an embodiment, the intermediate passivation structure may comprise an intermediate passivation area. The intermediate passivation area may comprise an area in which a side surface of the semiconductor stack structure is doped with N.

In an embodiment, the light emitting element may comprise a red light emitting element that emits red light.

An embodiment may provide a display device, comprising the light emitting element, and that allows the light emitting element to be supplied with energy of about 0.15 eV or less in case that the light emitting element emits light.

An embodiment may provide a method of manufacturing a light emitting element, that may include patterning a semiconductor stack layer on a growth substrate; forming an intermediate passivation structure on a side surface of the semiconductor stack structure; and forming an insulating layer comprising a metal oxide on the intermediate passivation structure. The semiconductor stack structure may comprise GaP. The intermediate passivation structure may comprise GaPₓN₍₁₋ₓ₎.

In an embodiment, the forming of the intermediate passivation structure may comprise forming an intermediate passivation layer comprising GaPₓN₍₁₋ₓ₎ on the side surface of the semiconductor stack structure.

In an embodiment, the forming of the intermediate passivation structure may comprise doping the side surface of the semiconductor stack structure with nitrogen (N).

In an embodiment, the insulating layer may comprise a metal oxide comprising at least one metal selected from a group comprising tantalum (Ta), hafnium (Hf), zirconium (Zr), lanthanum (La), silicon (Si), titanium (Ti), and aluminum (Al).

In an embodiment, the method may further comprise separating a structure comprising the semiconductor stack structure, the intermediate passivation structure, and the insulating layer.

In an embodiment, patterning the semiconductor stack structure may comprise sequentially growing semiconductor layers on the growth substrate; and etching the grown semiconductor layers.

An embodiment may provide a display device, comprising a base layer; and sub-pixels disposed on the base layer. Each of the sub-pixels may comprise series parts comprising light emitting elements, an anode connection electrode electrically connected to the series parts, and a cathode connection electrode electrically connected to the series parts. The sub-pixels may comprise a first sub-pixel that provides red light, a second sub-pixel that provides green light, and a third sub-pixel that provides blue light. The light emitting elements may comprise first light emitting elements comprised in the first sub-pixel, second light emitting elements comprised in the second sub-pixel, and third light emitting elements comprised in the third sub-pixel. The series parts may comprise r red series parts comprised in the first sub-pixel, g green series parts comprised in the second sub-pixel, and b blue series parts comprised in the third sub-pixel. Here, r is greater than g or b.

An embodiment may provide a display device, comprising a base layer; and sub-pixels disposed on the base layer, and comprising a first sub-pixel comprising a first light emitting element configured to emit red light, a second sub-pixel comprising a second light emitting element configured to emit green light, and a third sub-pixel comprising a third light emitting element configured to emit blue light. The first light emitting element may have a first size. The second light emitting element may have a second size. The third light emitting element may have a third size. The first size may be greater than the second size or the third size.

### BRIEF DESCRIPTION OF THE DRAWINGS

The above and other aspects and features of the disclosure will become more apparent by describing in detail embodiments thereof with reference to the attached drawings, in which:

FIG. 1 is a schematic sectional view illustrating a light emitting element in accordance with a first embodiment.

FIG. 2 is a schematic perspective view illustrating the light emitting element in accordance with the first embodiment.

FIG. 3 is a schematic enlarged sectional view illustrating a side portion of the light emitting element in accordance with the first embodiment.

FIG. 4 is a schematic sectional view illustrating a light emitting element in accordance with a second embodiment.

FIG. 5 is a schematic perspective view illustrating the light emitting element in accordance with the second embodiment.

FIG. 6 is a schematic enlarged sectional view illustrating a side portion of the light emitting element in accordance with the second embodiment.

FIG. 7 is a graph illustrating a trend of change in a bonding structure depending on energy applied to a light emitting element in accordance with an embodiment.

FIG. 8 is a schematic flowchart illustrating a method of manufacturing a light emitting element in accordance with an embodiment.

FIGS. 9 to 11 are schematic sectional views illustrating, by process steps, a method of manufacturing the light emitting element in accordance with an embodiment.

FIG. 12 is a schematic plan view illustrating a display device in accordance with an embodiment.

FIG. 13 is a schematic view illustrating a structure comprising a pixel circuit.

FIGS. 14 and 15 are schematic plan views each illustrating a display device in accordance with an embodiment.

FIGS. 16 and 17 are plan views schematically illustrating a structure for compensating for emission efficiency depending on the color of light emitted from a light emitting element in accordance with an embodiment.

### DETAILED DESCRIPTION OF THE EMBODIMENTS

As the disclosure allows for various changes and numerous embodiments, embodiments will be illustrated in the drawings and described in detail in the written description. However, this is not intended to limit the disclosure to selected modes of practice, and it is to be appreciated that all changes, equivalents, and substitutes that do not depart from the spirit and technical scope of the disclosure are encompassed in the disclosure.

In the drawings, sizes, thicknesses, ratios, and dimensions of the elements may be exaggerated for ease of description and for clarity. Like numbers refer to like elements throughout.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

In the disclosure, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Furthermore, in case that a first part such as a layer, a film, a region, or a plate is disposed on a second part, the first part may be not only directly on the second part but a third part may intervene between them. In addition, when it is expressed that a first part such as a layer, a film, a region, or a plate is formed on a second part, the surface of the second part on which the first part is formed is not limited to an upper surface of the second part but may comprise other surfaces such as a side surface or a lower surface of the second part. To the contrary, in case that a first part such as a layer, a film, a region, or a plate is under a second part, the first part may be not only directly under the second part but a third part (or other parts) may intervene between them.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Various embodiments of the disclosure relate to a light emitting element, a method of manufacturing the light emitting element, and a display device. Hereinafter, a light emitting element, a method of manufacturing the light emitting element, and a display device in accordance with an embodiment will be described with reference to the attached drawings.

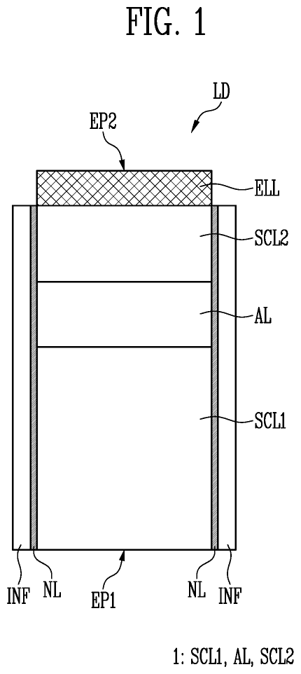

First, a light emitting element LD in accordance with an embodiment will be described with reference to FIGS. 1 to 7.

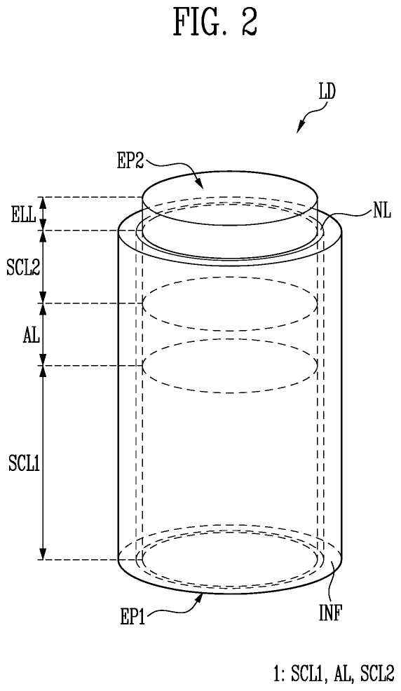

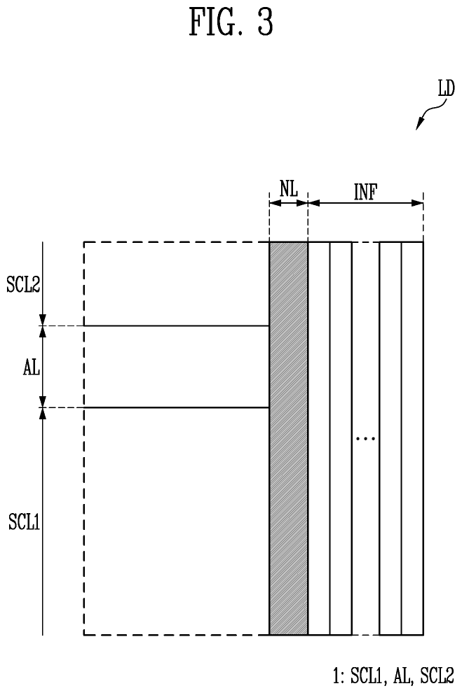

FIG. 1 is a schematic sectional view illustrating a light emitting element LD in accordance with a first embodiment. FIG. 2 is a schematic perspective view illustrating the light emitting element LD in accordance with the first embodiment. FIG. 3 is a schematic enlarged sectional view illustrating a side portion of the light emitting element LD in accordance with the first embodiment.

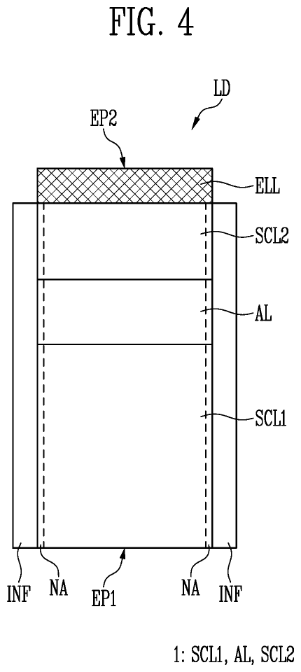

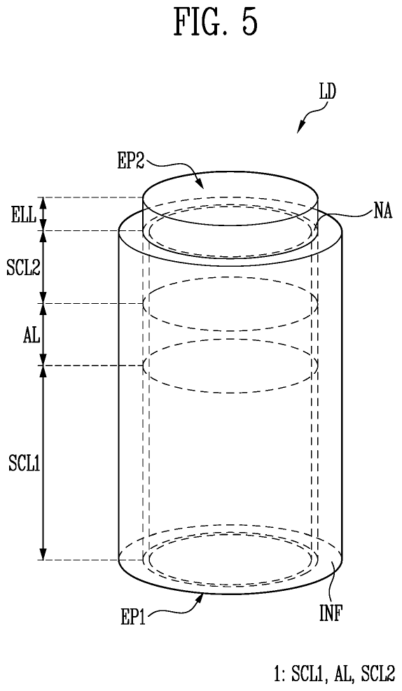

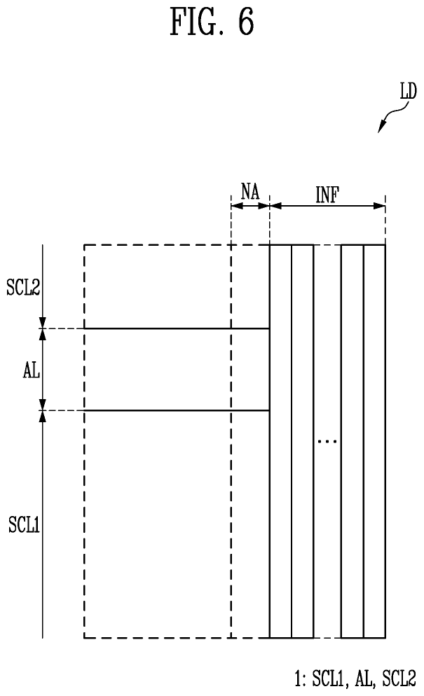

FIG. 4 is a schematic sectional view illustrating a light emitting element LD in accordance with a second embodiment. FIG. 5 is a schematic perspective view illustrating the light emitting element LD in accordance with the second embodiment. FIG. 6 is a schematic enlarged sectional view illustrating a side portion of the light emitting element LD in accordance with the second embodiment.

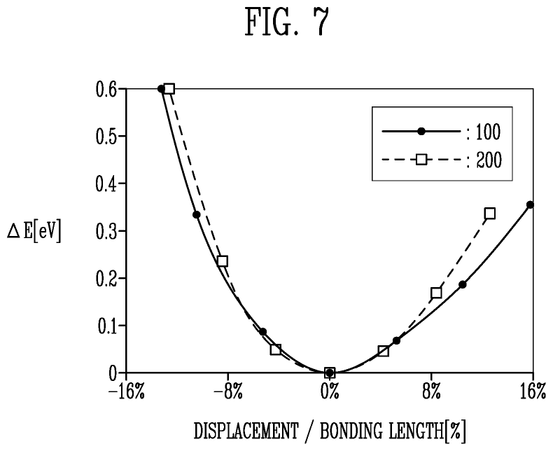

FIG. 7 is a graph illustrating a trend of change in a bonding structure depending on energy applied to a light emitting element LD in accordance with an embodiment.

The light emitting element LD may be configured to emit light. For example, the light emitting element LD may emit red light. Red light may have a wavelength band ranging from approximately 600 nm to approximately 750 nm. However, the disclosure is not limited to the foregoing. In the embodiment, the light emitting element LD may be a blue light emitting element configured to emit blue light, and a green light emitting element configured to emit green light. Hereinafter, with reference to FIGS. 1 to 11, description will be made, based on an embodiment in which the light emitting element LD is a red light emitting element.

The light emitting element LD may comprise a semiconductor stack structure 1, an intermediate passivation structure, and an insulating layer INF. The semiconductor stack structure 1 may comprise an N-type semiconductor layer SCL1, a P-type semiconductor layer SCL2, and an active layer AL disposed between the N-type semiconductor layer SCL1 and the P-type semiconductor layers SCL2. In an embodiment, the light emitting element LD may further comprise an electrode layer ELL on the P-type semiconductor layer SCL2.

The light emitting element LD may have various sizes. In an embodiment, the light emitting element LD may have a size ranging from the nanometer scale to the micrometer scale. For example, the diameter of the light emitting element LD may be about 100 μm or less. In an embodiment, the diameter of the light emitting element LD may be about 1 μm or less. Here, a criterion for measuring the diameter of the light emitting element LD may be determined depending on a cross-sectional shape of the light emitting element LD (for example, the active layer AL). For example, in the case where the cross-section of the light emitting element LD may have a circular shape, the diameter thereof may correspond to a diameter of the circle. In the case where the cross-section of the light emitting element LD has an elliptical shape, the diameter thereof may correspond to a length of a long side of the ellipse. In the case where the cross-section of the light emitting element LD has a polygonal shape, the diameter thereof may correspond to a length of a longest diagonal line of the polygon.

Experimentally, an etching process (for example, a dry etching process) for manufacturing the light emitting element LD may affect the emission efficiency of the light emitting element LD. For example, a side portion of the light emitting element LD may be damaged, so that there is a risk of damage to the active layer AL. The emission efficiency of the light emitting element LD may be damaged (for example, the emission efficiency may reduce due to an increase of non-radiative recombination). The risk may further increase as the size of the light emitting clement LD is reduced. For example, in the case where the size of the light emitting element LD is sufficiently large (for example, the size of the light emitting element LD is about 100 μm or more), the emission efficiency may be high in order of red light, blue light, and green light. However, as the size of the light emitting element LD is reduced, the emission efficiency of red light and blue light are reduced, so that the need for improvement in emission efficiency may be further increased. For example, in the case where the light emitting element LD is a red light emitting element, a structure for improving the emission efficiency may be needed.

In an embodiment, the light emitting element LD is characterized in that it comprises an intermediate passivation structure so that the emission efficiency can be improved. The intermediate passivation structure may be a layer or area comprising a crystalline structure having nitrogen (N). The intermediate passivation structure may be formed on a side surface of the semiconductor stack structure 1.

The intermediate passivation structure may be an intermediate passivation layer NL and/or an intermediate passivation area NA. For example, the light emitting element LD in accordance with the first embodiment (refer to FIGS. 1 to 3) may comprise an intermediate passivation layer NL. The light emitting element LD in accordance with the second embodiment (refer to FIGS. 4 to 6) may comprise an intermediate passivation area NA.

The intermediate passivation layer NL may be disposed on a side portion of the semiconductor stack structure 1. The intermediate passivation layer NL may be disposed on the semiconductor stack structure 1 and the insulating layer INF. In an embodiment, one surface of the intermediate passivation layer NL may contact the semiconductor stack structure 1, and the other surface of intermediate passivation layer NL may contact the insulating layer INF.

The intermediate passivation layer NL may be formed in such a way as to grow on a side portion of the semiconductor stack structure 1. The intermediate passivation layer NL may be a film formed separately from the insulating layer INF and the semiconductor stack structure 1. For example, the intermediate passivation layer NL may passivate at least a portion of the semiconductor stack structure 1.

The intermediate passivation area NA may be formed on a side portion of the semiconductor stack structure 1. The intermediate passivation area NA may be formed on a side surface of the semiconductor stack structure 1 directly adjacent to the insulating layer INF.

The intermediate passivation area NA may be an area formed by doping the side portion of the semiconductor stack structure 1 with N. For example, N applied to form the intermediate passivation area NA may form at least a portion of a crystalline structure on the side portion of the semiconductor stack structure 1.

The intermediate passivation layer NL and the intermediate passivation area NA may comprise GaPN-based material. For example, the intermediate passivation layer NL and the intermediate passivation area NA may comprise GaPₓN₍₁₋ₓ₎. The intermediate passivation layer NL and the intermediate passivation area NA may comprise AlₓIn_{y}Ga_{(1-y)}PzN_{(1-z)}.

The intermediate passivation layer NL and the intermediate passivation area NA may comprise a same material or a similar material as that of at least some of materials comprised in the semiconductor stack structure 1. For example, the semiconductor stack structure 1 may comprise GaP, and the intermediate passivation layer NL and the intermediate passivation area NA may comprise GaPN. The intermediate passivation layer NL and the intermediate passivation area NA may have a crystalline structure having a lattice constant corresponding to (or substantially a same as) that of the semiconductor stack structure 1. The intermediate passivation layer NL and the intermediate passivation area NA may form a buffer crystal structure between the semiconductor stack structure 1 and the insulating layer INF, so that a risk of occurrence of a defect in the semiconductor stack structure 1 due to lattice mismatch between the semiconductor stack structure 1 and the insulating layer INF can be reduced. Hence, the emission efficiency {for example, internal quantum efficiency (IQE)} of the light emitting element LD may be enhanced.

The light emitting element LD may comprise a first end EP1 and a second end EP2. In an embodiment, the N-type semiconductor layer SCL1 may be adjacent to the first end EP1 of the light emitting element LD. The P-type semiconductor layer SCL2 may be adjacent to the second end EP2.

The N-type semiconductor layer SCL1 may be disposed on the active layer AL and comprise a semiconductor layer having a type different from that of the P-type semiconductor layer SCL2. For example, the N-type semiconductor layer SCL1 may comprise an N-type semiconductor. For example, the N-type semiconductor layer SCL1 may comprise GaP-based material. The N-type semiconductor layer SCL1 may comprise GaP. The N-type semiconductor layer SCL1 may also comprise InₓAl_{y}Ga_{(1-x-y)}P. The N-type semiconductor layer SCL1 may comprise an N-type semiconductor layer doped with a first conductive dopant such as Si, Ge, or Sn. However, the disclosure is not limited to the foregoing example. The N-type semiconductor layer SCL1 may comprise various materials.

The active layer AL may be disposed between the N-type semiconductor layer SCL1 and the P-type semiconductor layer SCL2. The active layer AL may comprise a single-quantum well structure or a multi-quantum well structure. The position of the active layer AL may be changed in various ways depending on the type of the light emitting element LD, rather than being limited to a specific example.

The active layer AL may comprise a well layer and a barrier layer which are provided to form a quantum well structure. In an embodiment, the active layer AL may comprise InₓAl_{y}Ga_{(1-x-y)}P. As the contents of In and Al are adjusted, a portion of the active layer AL may form a well layer, and another portion of the active AL may form a barrier layer. In an embodiment, the wavelength of light emitted from the light emitting element may be determined by controlling the content of each ingredient of InₓAl_{y}Ga_{(1-x-y)}P and a crystal structure thereof. However, the disclosure is not limited to the foregoing.

The P-type semiconductor layer SCL2 may be disposed on the active layer AL and comprise a semiconductor layer having a type different from that of the N-type semiconductor layer SCL1. For example, the P-type semiconductor layer SCL2 may comprise a P-type semiconductor. For example, the P-type semiconductor layer SCL2 may comprise GaP-based material. The P-type semiconductor layer SCL2 may comprise GaP. The P-type semiconductor layer SCL2 may also comprise InₓAl_{y}Ga_{(1-x-y)}P. The P-type semiconductor layer SCL2 may comprise a P-type semiconductor layer doped with a second conductive dopant such as Ga, B, or Mg. However, the disclosure is not limited to the foregoing example. The P-type semiconductor layer SCL2 may comprise various materials.

The electrode layer ELL may be disposed on the P-type semiconductor layer SCL2. The electrode layer ELL may be adjacent to the second end EP2. The electrode layer ELL may be an ohmic electrode, and a portion of the electrode layer ELL may be exposed. In an embodiment, the electrode layer ELL may comprise one or more selected from the group consisting of chrome (Cr), titanium (Ti), aluminum (Al), gold (Au), nickel (Ni), and oxide or an alloy thereof. However, the disclosure is not limited to the foregoing example.

In an embodiment, the structure of the light emitting element LD is not limited thereto, and may further comprise an additional layer(s). For example, the light emitting element LD may further comprise an electron blocking layer configured to prevent electrons from overflowing. The light emitting element LD may further comprise a superlattice layer configured to relieve stress in the light emitting element LD.

In the case where a voltage of a threshold voltage or more is applied between the first end EP1 and the second end EP2 of the light emitting element LD, an electron-hole pair in the active layer AL may be recombined, and the light emitting element LD may emit light. Since light emission of the light emitting element LD can be controlled based on the foregoing principle, the light emitting element LD may be used as a light source in various devices.

The insulating layer INF may be disposed on a side portion of the semiconductor stack structure 1. The insulating layer INF may be disposed on the semiconductor stack structure 1 comprising the N-type semiconductor layer SCL1, the active layer AL, and the P-type semiconductor layer SCL2. For example, in the first embodiment, the insulating layer INF may be disposed on the intermediate passivation layer NL. In the second embodiment, the insulating layer INF may be disposed on the intermediate passivation area NA. The insulating layer INF may protect the semiconductor stack structure 1 from external effects, and may insulate the N-type semiconductor layer SCL1, the active layer AL, and the P-type semiconductor layer SCL2 from the outside.

The insulating layer INF may comprise insulating material comprising metal oxide. For example, the insulating layer INF may comprise metal oxide comprising at least one metal selected from the group consisting of tantalum (Ta), hafnium (Hf), zirconium (Zr), lanthanum (La), silicon (Si), titanium (Ti), and aluminum (Al). However, the disclosure is not limited to a specific example.

In an embodiment, the insulating layer INF may comprise two or more insulating layers. For example, the insulating layer INF may have a structure in which two or more insulating layers comprising different materials may be successively stacked each other. For example, the insulating layer INF may comprise a first insulating layer comprising M1_{X}O_{Y} and a second insulating layer M2_{U}O_{Z} (M1 and M2 are metal). The number of insulating layers for forming the insulating layer INF is not particularly limited.

In an embodiment, the metal oxide that forms the insulating layer INF may be determined to have bonding energy greater than that of the material that forms the semiconductor stack structure 1. Influence of the insulating layer INF on the semiconductor stack structure 1 may be minimized, and the insulating layer INF may be more stably formed.

In an embodiment, even if the insulating layer INF may comprise metal oxide, the intermediate passivation structure may reduce a risk of permeation of the metal that forms the insulating layer INF into the semiconductor stack structure 1. For example, the intermediate passivation structure may comprise a crystal structure comprising GaPN. N may have an ion radius of approximately 1.46 A. In the case where N and Ga form a bonding structure, N and Ga may be spaced apart from each other by approximately 1.84 Å. A distance between atoms in the metal oxide that forms the insulating layer INF may be approximately 2.0 Å. Hence, it may be difficult for the metal oxide to be penetrated into (substituted for) the intermediate passivation structure comprising GaPN. Consequently, influence of the insulating layer INF on the semiconductor stack structure 1 may be reduced.

Experimentally, in the case where undesired metal material is penetrated into the semiconductor stack structure 1, stress may occur due to lattice mismatch between the penetrant metal material and the semiconductor stack structure 1. However, as described above, the intermediate passivation structure comprises GaPN, thus making the penetration of metal material into the semiconductor stack structure 1 difficult, whereby the above-stated risk can be substantially removed.

For example, in the case where one material is added to the semiconductor crystal structure, structural characteristics of the semiconductor crystal structure may be changed depending on characteristics (for example, the number of peripheral electrons, or the like) of the added crystal structure. For example, in the case where the semiconductor stack structure 1 has a crystal structure comprising GaP, if oxygen (O) is penetrated into the crystal structure comprising the GaP, a bonding length between atoms in the crystal structure (for example, a hexagonal crystal structure, or the like) that is formed by GaP may be partially changed.

Therefore, in the case where the semiconductor stack structure 1 comprises GaP, there is a need to reduce the risk of distortion of the crystal structure due to penetration of O into the semiconductor stack structure 1. In an embodiment, the intermediate passivation structure may reduce the risk of penetration of the material that forms the insulating layer INF into the semiconductor stack structure 1. For example, the intermediate passivation structure may have a crystal structure comprising GaPN. Here, a distance between the centers of the respective atoms of Ga and N may be approximately 1.84 Å, and the ion radius of N may be approximately 1.46 Å. Hence, it may be difficult for oxygen (O) to pass through GaPN and reach the crystal structure comprising GaP. Therefore, the risk of occurrence of a structural defect of the crystal structure that forms the semiconductor stack structure 1 may be reduced.

In accordance with an embodiment, to allow the light emitting element LD to emit, energy of about 0.15 eV or less may be supplied to the semiconductor stack structure 1. By way of example, to allow the light emitting element LD to emit, energy of about 0.1 eV or less may be supplied to the semiconductor stack structure 1. For example, in case that the light emitting element LD is driven to emit light, the light emitting element LD may be controlled such that energy or about 0.15 eV or less (or about 0.1 eV or less) is supplied between the first end EP1 and the second end EP2 of the light emitting element LD.

Hence, in accordance with an embodiment, the risk of occurrence of a structural defect of the crystal structure in the semiconductor stack structure 1 may be reduced. Technical characteristics pertaining to the foregoing will be described with reference to FIG. 7.

Experimentally, to allow the light emitting element LD to emit light, a potential difference of a threshold voltage or more may be formed, so that work energy can be supplied to the light emitting element LD. Here, as the supplied energy is increased, the probability of occurrence of a structural defect in the crystal structure of the semiconductor stack structure 1 may be increased. For example, due to an increase in the supplied energy, the bonding length between the atoms in the crystal structure may be changed. In other words, due to an increase in the supplied energy, the positions of the atoms in the crystal structure may be shifted. There is a need to mitigate a structural defect of the light emitting element LD. By way of example, in the case where the crystal structure comprising GaPN comprised in the intermediate passivation structure is changed, strain resulting from the change in the crystal structure may be applied to the semiconductor stack structure 1. Therefore, there is a need to minimize the change in the crystal structure.

The degree to which the crystal structure is changed by the supply of energy may be increased as the amount with which different materials are comprised in the crystal structure is increased. For example, in the case of the crystal structure comprising GaPN, the degree to which the bonding length between the atoms is changed by the supply of energy may be greater than that of the crystal structure comprising GaN.

However, in an embodiment, in the case where energy to be supplied to the semiconductor stack structure 1 is within a selected energy level range, GaPN and GaN may be similar to each other in trend in which the bonding structure is changed by the supply of energy. In other words, in an embodiment, the range of energy to be supplied in case that the light emitting element LD emits light may be limited to a selected level range, whereby occurrence of the structural defect of the crystal structure in the light emitting element LD may be minimized. For example, as described above, the intermediate passivation structure may comprise GaPN, and the bonding structure of GaPN may be changed to be similar to the bonding structure GaN within the selected level range of applied energy.

In FIG. 7, a first graph 100 illustrates a rate of a displacement of P based on an initial position (or a reference position) in case that work energy is supplied, compared to an initial bonding length between phosphate (P) and Ga, in the bonding structure of GaPN. A second graph 200 illustrates a rate (%) of a displacement of N based on an initial position (or a reference position) in case that work energy is supplied, compared to an initial bonding length between N and Ga, in the bonding structure of GaPN.

Referring to FIG. 7, it can be checked that, in the case where energy supplied in case that the light emitting element LD emits light is about 0.15 eV or less, the trends of the change in the bonding structures of GaPN and GaN are substantially similar to each other. In the bonding structure of GaPN, a displacement of P based on a reference position may be within about 8% (or may be determined within about 8%) compared to a bonding length between Ga and P. In an embodiment, in the case where energy supplied in case that the light emitting element LD emits light is about 0.1 eV or less, the trends of the change in the bonding structures of GaPN and GaN are increasingly similar to each other. The reference position of P may be a position of P in the crystal structure GaPN in case that separate energy is not supplied.

Consequently, although the semiconductor stack structure 1 in accordance with an embodiment comprises GaP-based material, the intermediate passivation structure comprises GaPN, so that a structural defect resulting from lattice mismatch can be prevented from occurring. Furthermore, the light emitting element LD may be operated within an energy level range in which a structural distortion related to the crystal structure in the intermediate passivation structure comprising GaPN can be substantially minimized. Therefore, a structural risk resulting from introduction of the intermediate passivation structure comprising GaPN may be prevented from occurring.

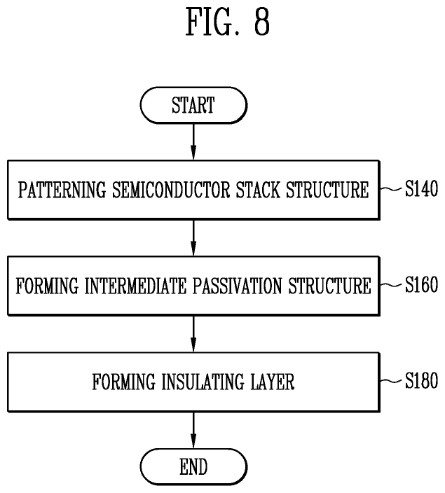

Hereinafter, a method of manufacturing the light emitting element LD in accordance with an embodiment will be described with reference to FIGS. 8 to 11. Description overlapping that of the contents described above will be simplified, or may not be repeated.

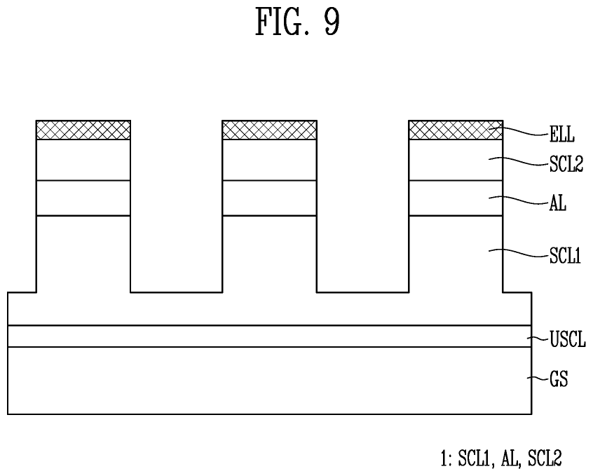

FIG. 8 is a schematic flowchart illustrating a method of manufacturing a light emitting clement in accordance with an embodiment. FIGS. 9 to 11 are schematic sectional views illustrating, by process steps, a method of manufacturing the light emitting element in accordance with an embodiment.

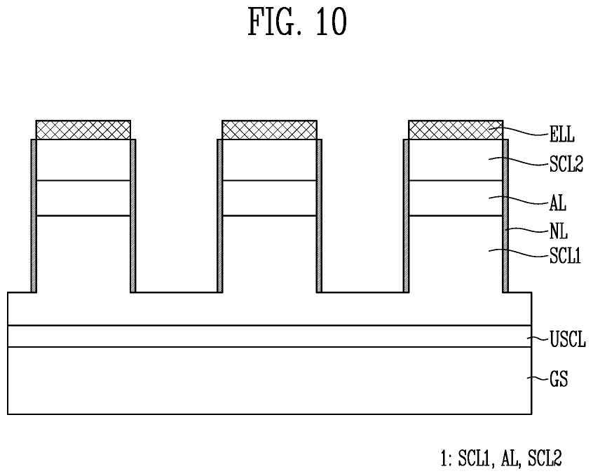

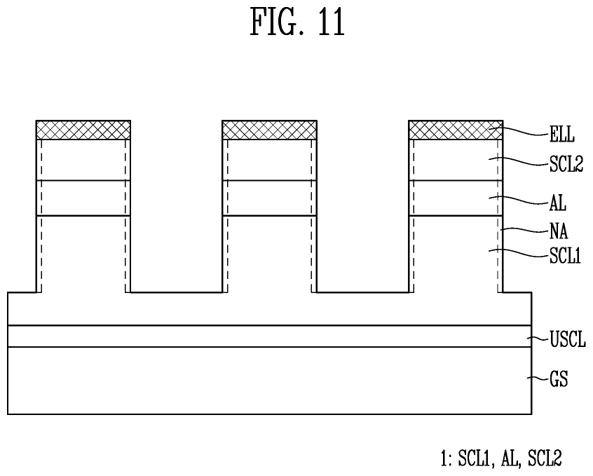

FIG. 10 schematically illustrates the step of forming the intermediate passivation layer NL in a process of manufacturing the light emitting element LD in accordance with the first embodiment. FIG. 11 schematically illustrates the step of forming the intermediate passivation layer NL in a process of manufacturing the light emitting element LD in accordance with the second embodiment.

Referring to FIG. 8, the method of manufacturing the light emitting element LD in accordance with an embodiment may comprise step S140 of patterning a semiconductor stack structure, step S160 of forming an intermediate passivation structure, and step S180 of forming an insulating layer.

Referring to FIGS. 8 and 9, at step S140 of patterning the semiconductor stack structure, the semiconductor stack structure 1 may be patterned by growing an undoped semiconductor layer USCL, an N-type base semiconductor layer, a base active layer, and a P-type base semiconductor layer on a growth substrate GS, and etching at least a portion of each of the N-type base semiconductor layer, the base active layer, and the P-type base semiconductor layer.

The growth substrate GS may be a base board provided to grow a target material. For example, the growth substrate GS may be a wafer for epitaxial growth of the target material. The growth substrate GS may be a substrate comprising GaP, and material for forming the growth substrate GS is not limited to a particular example.

The undoped semiconductor layer USCL may minimize defects in the semiconductor layers formed on the growth substrate GS. In an embodiment, the undoped semiconductor layer USCL may comprise semiconductor material which does not comprise a separate dopant, but the material for forming the undoped semiconductor layer USCL is not limited to a particular example.

The N-type base semiconductor layer, the base active layer, and the P-type base semiconductor layer may be formed by sequential epitaxial growth. The N-type base semiconductor layer may comprise material for forming the N-type semiconductor layer SCL1. The base active layer may comprise material for forming the active layer AL. The P-type base semiconductor layer may comprise material for forming the P-type semiconductor layer SCL2.

In an embodiment, after the semiconductor stack structure 1 is patterned, the electrode layer ELL may be patterned. In an embodiment, the electrode layer ELL may be manufactured by etching a base electrode layer formed through a sputtering process. However, the disclosure is not limited to the foregoing. Depending on the embodiment, a time point of the process of forming the electrode layer ELL and a deposition method thereof may be appropriately changed.

Referring to FIGS. 8 to 10, at step S160 of forming the intermediate passivation structure, the intermediate passivation layer NL or the intermediate passivation area NA may be formed.

For example, referring to FIGS. 8 and 9, the intermediate passivation layer NL may be formed on the semiconductor stack structure 1 to manufacture the light emitting element LD in accordance with the first embodiment. For example, material for forming the intermediate passivation layer NL may be epitaxially grown on the semiconductor stack structure 1. For example, material comprising GaPN may be grown on the semiconductors tack structure 1. By way of example, material comprising GaN may be grown on the semiconductor stack structure 1, and the intermediate passivation layer NL comprising GaPN may be formed by forming a bonding structure with GaP comprised in an outer portion of the semiconductor stack structure 1.

In another example, referring to FIGS. 8 and 10, the intermediate passivation area NA may be formed on a portion of the semiconductor stack structure 1 to manufacture the light emitting element LD in accordance with the second embodiment. For instance, the outer portion of the semiconductor stack structure 1 may be doped with N, so that a crystal structure comprising GaPN may be formed on a side portion of the semiconductor stack structure 1 to provide the intermediate passivation area NA.

At step S180 of forming the insulating layer, the insulating layer INF may be patterned, so that the insulating layer INF can cover the semiconductor stack structure 1.

For example, the insulating layer INF may be formed (or deposited) by various methods. For instance, an atomic layer deposition (ALD) process, a chemical vapor deposition (CVD) process, or the like may be used. However, the disclosure is not limited to the foregoing. The formed insulating layer INF may be etched so that the semiconductor stack structure 1 may be electrically exposed.

In an embodiment, because the intermediate passivation structure is formed before the insulating layer INF is formed, the influence of the insulating layer INF on the semiconductor stack structure 1 may be reduced.

In an embodiment, the insulating layer INF may be formed by alternately forming different materials so as to comprise two or more insulating layers. As described above, the insulating layer INF may comprise metal oxide.

In an embodiment, the step of providing individual light emitting elements LD by separating a structure comprising the semiconductor stack structure 1 and the insulating layer INF may be further performed. For example, a portion of the N-type semiconductor layer SCL1 may be cut along a cutting line CL. In an embodiment, a laser lift off (LLO) process may be performed to cut a portion of the N-type semiconductor layer SCL1. However, the disclosure is not limited to the foregoing. Depending on the embodiment, the step of separating the structure comprising the semiconductor stack structure 1 and the insulating layer INF may not be performed, and the light emitting element LD may be manufactured by transferring a structure comprising the semiconductor stack structure 1 onto a backplane layer (for example, a pixel circuit layer comprising a pixel circuit), and removing the growth substrate GS or the like within the spirit and the scope of the disclosure.

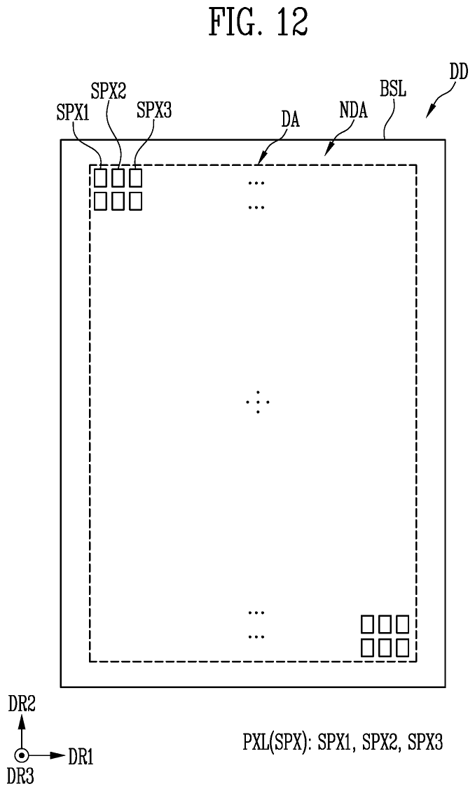

Hereinafter, a display device DD comprising the light emitting element LD in accordance with an embodiment will be described with reference to FIGS. 12 to 17. Description overlapping that of the contents described above will be simplified, or may not be repeated.

FIG. 12 is a schematic plan view illustrating a display device DD in accordance with an embodiment.

Referring to FIG. 12, the display device DD may comprise a base layer BSL, and pixels PXL disposed on the base layer BSL. Although not illustrated in the drawing, the display device DD may further comprise a driving circuit component (for example, a scan driver and a data driver), lines, and pads which are configured to drive the pixels PXL.

The display device DD (or the base layer BSL) may comprise a display area DA and a non-display area NDA. The non-display area NDA may refer to an area other than the display area DA. The non-display area NDA may enclose at least a portion of the display area DA.

The base layer BSL may form a base surface of the display device DD. The base layer BSL may be a rigid or flexible substrate or film. For example, the base layer BSL may be a rigid substrate made of glass or reinforced glass, a flexible substrate (or a thin film) formed of plastic or metal, or at least one insulating layer. The material and/or properties of the base layer BSL are not particularly limited. In an embodiment, the base layer BSL may be substantially transparent. Here, the words “substantially transparent” may mean that light can pass through the base layer BSL with a transmittance of a selected value or more. In an embodiment, the base layer BSL may be translucent or opaque. Furthermore, the base layer BSL may comprise reflective material depending on the embodiment.

The display area DA may refer to an area in which the pixels PXL are disposed. The non-display area NDA may refer to an area in which the pixels PXL are not disposed. The driving circuit component, the lines, and the pads which are connected to the pixels PXL of the display area DA may be disposed in the non-display area NDA. The pixel PXL (or sub-pixels SPX) may be disposed on the base layer BSL.

In accordance with an embodiment, the pixels PXL (or the sub-pixels SPX) may be arranged or disposed in a stripe or PENTILETM arrangement structure or the like, but the disclosure is not limited thereto. Various embodiments may be applied to the disclosure.

In accordance with an embodiment, the pixel PXL (or the sub-pixels SPX) may comprise a first sub-pixel SPX1, a second sub-pixel SPX2, and a third sub-pixel SPX3. In an embodiment, the sub-pixel SPX may comprise a light emitting element LD. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form one pixel unit which may emit various colors of light.

For example, each of the first sub-pixel SPX1, the second sub-pixel SPX2, and the third sub-pixel SPX3 may emit a color of light. For instance, the first sub-pixel SPX1 may be a red pixel configured to emit red (for example, first color) light, the second sub-pixel SPX2 may be a green pixel configured to emit green (for example, second color) light, and the third sub-pixel SPX3 may be a blue pixel configured to emit blue (for example, third color) light. In accordance with an embodiment, the number of second sub-pixels SPX2 may be greater than the number of first sub-pixels SPX1, or the number of third sub-pixels SPX3. The colors, types, and/or numbers of first sub-pixels SPX1, second sub-pixels SPX2, and the third sub-pixels SPX3 which form each pixel unit is not limited to a specific example.

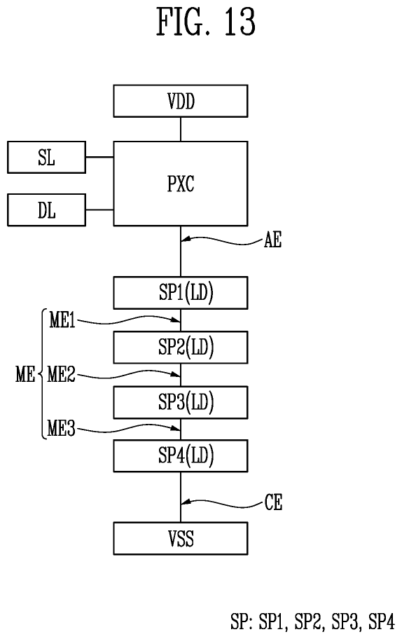

The display device DD comprising one or more series parts SP cach comprising light emitting element LD will be described with reference to FIGS. 13 to 15. The display device DD in accordance with an embodiment may have a structure in which light emitting elements LD are aligned on one or more alignment electrodes. However, the disclosure is not limited to the foregoing. For example, the display device DD may be a device manufactured by transferring the light emitting elements LD onto the base layer BSL (or the backplane layer).

In an embodiment, the display device DD may comprise the series parts SP which are electrically connected in series to each other. The number of series parts SP are not particularly limited. In FIGS. 13 to 15, technical characteristics pertaining to the series parts SP will be described based on an embodiment comprising four series parts SP. For example, the display device DD in accordance with an embodiment will be described based on a structure in which the series parts SP comprise first to fourth series parts SP1, SP2, SP3, and SP4.

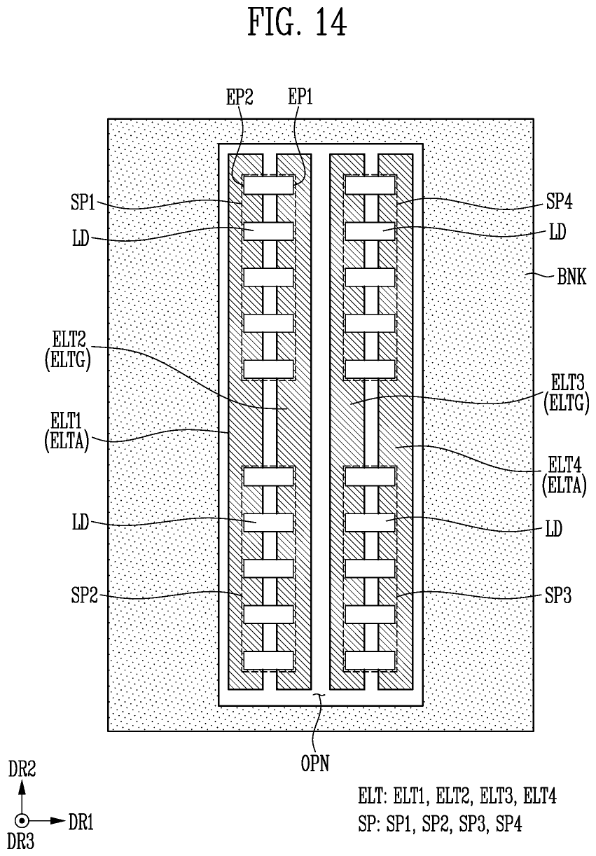

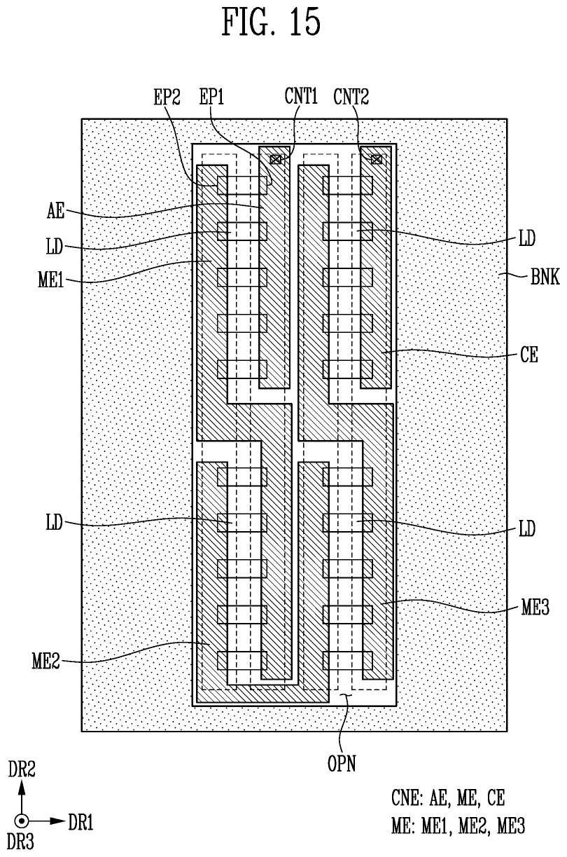

FIG. 13 is a schematic view illustrating a structure comprising a pixel circuit PXC. FIGS. 14 and 15 are schematic plan views each illustrating the display device DD in accordance with an embodiment. FIGS. 14 and 15 illustrate a same area. FIG. 14 schematically illustrates a bank BNK, series parts SP, and an alignment electrode layer ELT in accordance with an embodiment. FIG. 15 schematically illustrates a bank BNK, series parts SP, and a connection electrode layer CNE in accordance with an embodiment.

The display device DD may comprise a pixel circuit layer comprising the pixel circuit PXC disposed on the base layer BSL, and a light-emitting-element layer on which the light emitting elements LD are disposed.

The pixel circuit layer may comprise the base layer BSL, conductive layers formed to form pixel circuits PXC, and insulating layers disposed between the conductive layers.

The light-emitting-element layer may be disposed on the pixel circuit layer. In an embodiment, the light-emitting-element layer may comprise light emitting elements LD. The light emitting elements LD may be aligned on the alignment electrode layer ELT. The light emitting elements LD may form (or constitute) the series parts SP. The light emitting elements LD may be electrically connected in parallel to each other in the series parts SP.

In an embodiment, the series parts SP may comprise a first series part SP1, a second series part SP2, a third series part SP3, and a fourth series part SP4. Intermediate connection electrodes ME may comprise a first intermediate connection electrode ME1, a second intermediate connection electrode ME2, and a third intermediate connection electrode ME3.

The first series part SP1, the second series part SP2, the third series part SP3, and the fourth series part SP4 may be electrically connected to each other.

The light emitting elements LD that are comprised in the first series part SP1 may be electrically connected in parallel to each other, and may be electrically connected in series between the pixel circuit PXC and the second series part SP2. The first ends EP1 of the light emitting elements LD that are comprised in the first series part SP1 may be electrically connected to the pixel circuit PXC by an anode connection electrode AE. The second ends EP2 of the light emitting elements LD that are comprised in the first series part SP1 may be electrically connected to the light emitting elements LD that are comprised in the second series part SP2 by the first intermediate connection electrode ME1.

The light emitting elements LD that are comprised in the second series part SP2 may be electrically connected in parallel to each other, and may be electrically connected in series between the light emitting elements LD that are comprised in the first series part SP1 and the light emitting elements LD that are comprised in the third series part SP3. The first ends EP1 of the light emitting elements LD that are comprised in the second series part SP2 may be electrically connected to the light emitting elements LD that are comprised in the first series part SP1 by the first intermediate connection electrode ME1. The second ends EP2 of the light emitting elements LD that are comprised in the second series part SP2 may be electrically connected to the light emitting elements LD that are comprised in the third series part SP3 by the second intermediate connection electrode ME2.

The light emitting elements LD that are comprised in the third series part SP3 may be electrically connected in parallel to each other, and may be electrically connected in series between the light emitting elements LD that are comprised in the second series part SP2 and the light emitting elements LD that are comprised in the fourth series part SP4. The first ends EP1 of the light emitting clements LD that are comprised in the third series part SP3 may be electrically connected to the light emitting elements LD that are comprised in the second series part SP2 by the second intermediate connection electrode ME2. The second ends EP2 of the light emitting elements LD that are comprised in the third series part SP3 may be electrically connected to the light emitting elements LD that are comprised in the fourth series part SP4 by the third intermediate connection electrode ME3.

The light emitting elements LD that are comprised in the fourth series part SP4 may be electrically connected in parallel to each other, and may be electrically connected in series between the light emitting elements LD that are comprised in the third series part SP3 and a second power supply VSS. The first ends EP1 of the light emitting elements LD that are comprised in the fourth series part SP4 may be electrically connected to the light emitting elements LD that are comprised in the third series part SP3 by the third intermediate connection electrode ME3. The second ends EP2 of the light emitting elements LD that are comprised in the fourth series part SP4 may be electrically connected to the second power supply VSS by a cathode connection electrode CE.

In an embodiment, the first ends EP1 of the light emitting elements LD of each of the first series part SP1 and the second series part SP2 may face a second electrode ELT2 (for example, a second alignment electrode ELTG). The second ends EP2 of the light emitting elements LD of each of the first series part SP1 and the second series part SP2 may face a first electrode ELT1 (for example, a first alignment electrode ELTA).

In an embodiment, the first ends EP1 of the light emitting elements LD of each of the third series part SP3 and the fourth series part SP4 may face a third electrode ELT3 (for example, the second alignment electrode ELTG). The second ends EP2 of the light emitting elements LD of each of the third series part SP3 and the fourth series part SP4 may face a fourth electrode ELT4 (for example, the first alignment electrode ELTA).

The pixel circuit PXC may comprise one or more transistors. For instance, the pixel circuit PXC may comprise a driving transistor, and a storage capacitor. Each of the one or more transistors may be a thin film transistor.

The pixel circuit PXC may be electrically connected to a scan line SL and a data line DL. The pixel circuit PXC may be electrically connected to a first power supply VDD. The cathode connection electrode CE may be electrically connected to the second power supply VSS. The first power supply VDD may supply power having a potential higher than that of the second power supply VSS. Hence, a potential difference may be formed between the anode connection electrode AE and the cathode connection electrode CE, so that the light emitting element LD may emit light based on an electrical signal supplied from the pixel circuit PXC. In an embodiment, the anode connection electrode AE may be electrically connected, through a first contactor CNT1, to the pixel circuit PXC and the first power line PLI provided for the supply of the voltage of the first power supply VDD. The cathode connection electrode CE may be electrically connected, through a second contactor CNT2, to a second power line PL2 provided for the supply of the voltage of the second power supply VSS.

In an embodiment, the light emitting elements LD may be disposed in an area enclosed by the bank BNK. For example, the bank BNK may form an opening OPN. The bank BNK may be disposed on the pixel circuit layer (or the base layer BSL).

The opening OPN may comprise an area in which the bank BNK is not disposed. The opening OPN may comprise an area enclosed by the bank BNK. The bank BNK may protrude in a thickness direction (for example, a third direction DR3) and enclose one area or an area, and may form the opening OPN.

The bank BNK may comprise various organic materials. For example, the bank BNK may comprise organic material such as acrylic resin, epoxy resin, phenol resin, polyamide resin, polyimide resin, polyester resin, polyphenylene sulfide resin, or benzocyclobutene (BCB). However, the disclosure is not limited to the foregoing example.

Ink comprising light emitting elements LD may be supplied to the opening OPN defined by the bank BNK so that the light emitting elements LD may be disposed in the opening OPN.

In an embodiment, the display device DD may comprise an alignment electrode ELT. The alignment electrode layer ELT may comprise an electrode structure for aligning the light emitting elements LD.

The alignment electrode layer ELT may be disposed on the pixel circuit layer (or the base layer BSL). The alignment electrode layer ELT may comprise a first electrode ELT1, a second electrode ELT2, a third electrode ELT3, and a fourth electrode ELT4. In an embodiment, the light emitting elements LD may be aligned between the first alignment electrode ELTA to which a first alignment signal is to be supplied, and the second alignment electrode ELTG to which a second alignment signal different from the first alignment signal is to be supplied. The first electrode ELT1 and the fourth electrode ELT4 may be the first alignment electrode ELTA. The second electrode ELT2 and the third electrode ELT3 may be the second alignment electrode ELTG.

The first alignment electrode ELTA may be an electrode to which an AC signal can be supplied to align the light emitting elements LD. The first alignment electrode ELTA may be an electrode to which an anode signal can be supplied to allow the light emitting elements LD to emit light. The second alignment electrode ELTG may be an electrode to which a ground signal can be supplied to align the light emitting elements LD. The second electrode ELT2 may be an electrode to which a cathode signal can be supplied to allow the light emitting elements LD to emit light.

The first alignment electrode ELTA and the second alignment electrode ELTG may be respectively supplied (or provided) with a first alignment signal and a second alignment signal during a process of aligning the light emitting elements LD. For example, ink comprising the light emitting elements LD may be supplied (or provided) to the opening OPN, the first alignment signal may be supplied to the first alignment electrode ELTA, and the second alignment signal may be supplied to the second alignment electrode ELTG. Here, the first alignment signal and the second alignment signal may have different waveforms, different potentials, and/or different phases. For example, the first alignment signal may be an AC signal, and the second alignment signal may be a ground signal. However, the disclosure is not limited to the foregoing example. An electric field may be formed between the first alignment electrode ELTA and the second alignment electrode ELTG, so that the light emitting elements LD may be aligned between the first alignment electrode ELTA and the second alignment electrode ELTG based on the electric field. For example, the light emitting elements LD may be moved (or rotated) by force {for example, dielectrophoresis (DEP) force} derived from the electric field and thus be aligned (or disposed) on the first alignment electrode ELTA and the second alignment electrode ELTG.

In an embodiment, the first electrode ELT1, the second electrode ELT2, the third electrode ELT3, and the fourth electrode ELT4 may be successively arranged or disposed in the first direction DR1, and may extend in the second direction DR2.

The light emitting elements LD may be disposed (or aligned) on the alignment electrode layer ELT. In an embodiment, the light emitting elements LD may be aligned between the first alignment electrode ELTA and the second alignment electrode ELTG, in a plan view. The first end EP1 of the light emitting element LD may be disposed adjacent to the second alignment electrode ELTG. The second end EP2 of the light emitting element LD may be disposed adjacent to the first alignment electrode ELTA.

At least a portion of the connection electrode layer CNE may be disposed in the opening OPN, and may be electrically connected to the light emitting element LD. At least a portion of the intermediate connection electrode ME may be bent one or more. Hence, the intermediate connection electrode ME may electrically connect the light emitting elements LD to each other to allow the light emitting elements LD to form an appropriate electrical path. For example, the first ends EP1 of the light emitting elements LD that are comprised in the first series part SP1 may face the anode connection electrode AE. The second ends EP2 of the light emitting elements LD that are comprised in the first series part SP1 may face the first intermediate connection electrode ME1. The first ends EP1 of the light emitting elements LD that are comprised in the second series part SP2 may face the first intermediate connection electrode ME1. The second ends EP2 of the light emitting elements LD that are comprised in the second series part SP2 may face the second intermediate connection electrode ME2. The first ends EP1 of the light emitting elements LD that are comprised in the third series part SP3 may face the second intermediate connection electrode ME2. The second ends EP2 of the light emitting elements LD that are comprised in the third series part SP3 may face the third intermediate connection electrode ME3. The first ends EP1 of the light emitting elements LD that are comprised in the fourth series part SP4 may face the third intermediate connection electrode ME3. The second ends EP2 of the light emitting elements LD that are comprised in the fourth series part SP4 may face the cathode connection electrode CE.

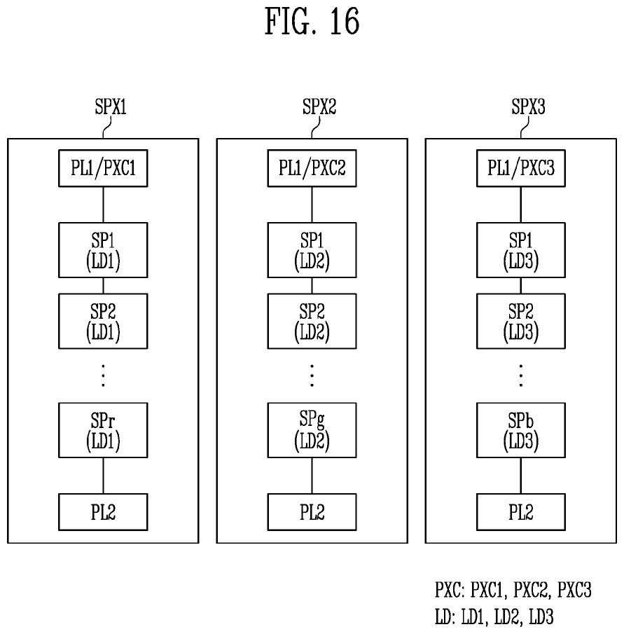

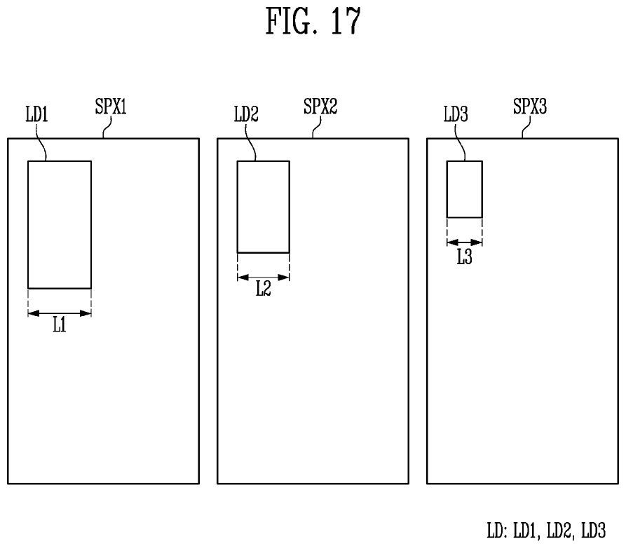

The display device DD in accordance with an embodiment may comprise a structure configured to compensate for the emission efficiency depending on the color of light emitted from the light emitting element LD. Related description will be made with referent to FIGS. 16 and 17.

FIGS. 16 and 17 are plan views schematically illustrating a structure for compensating for the emission efficiency depending on the color of light emitted from a light emitting element in accordance with an embodiment.

Referring to FIG. 16, the display device DD may comprise a structure in which the sub-pixels SPX differ from each other in the number of series parts SP comprised in each of the sub-pixels SPX, as the structure configured to compensate for the emission efficiency depending on the color of light emitted from the light emitting element LD.

As described above, the display device DD may comprise a structure in which one or more series SP are electrically connected to each other. Depending on the number of series parts SP, the luminance of each of the sub-pixels SPX may be changed. In an embodiment, the number of the series parts SP may be determined, taking into account the emission efficiency of the light emitting elements LD comprised in each of the sub-pixels SPX. Due to the number of light emitting elements LD that are changed depending on the number of series parts SP, a deviation in emission efficiency between the light emitting elements LD comprised in each of the sub-pixels SPX may be compensated for.

For example, the light emitting elements LD may comprise a first light emitting clement LD1 configured to emit red light, a second light emitting element LD2 configured to emit green light, and a third light emitting element LD3 configured to emit blue light. The pixel circuits PXC may comprise a first pixel circuit PXCI configured to drive the first sub-pixel SPX1, a second pixel circuit PXC2 configured to drive the second sub-pixel SPX2, and a third pixel circuit PXC3 configured to drive the third sub-pixel SPX3.

The first sub-pixel SPX1 may comprise the first light emitting elements LD1. The first light emitting elements LD1 may be comprised in each of the series parts SP. For example, the first sub-pixel SPX1 may comprise first to r-th series parts SP1, SP2, . . . , and SPr electrically connected in series to each other. For example, the first sub-pixel SPX1 may comprise r series parts SP. The series parts SP of the first sub-pixel SPX1 may be electrically connected to the second power line PL2 and the first pixel circuit PXCI that is electrically connected to the first power line PLI. In an embodiment, the series parts SP of the first sub-pixel SPX1 may be referred to as red series parts.

The second sub-pixel SPX2 may comprise the second light emitting elements LD2. The second light emitting elements LD2 may be comprised in each of the series parts SP. For example, the first sub-pixel SPXI may comprise first to g-th series parts SP1, SP2, . . . , and SPg electrically connected in series to each other. For example, the second sub-pixel SPX2 may comprise g series parts SP. The series parts SP of the second sub-pixel SPX2 may be electrically connected to the second power line PL2 and the second pixel circuit PXC2 that is electrically connected to the first power line PLI.

The third sub-pixel SPX3 may comprise the third light emitting elements LD3. The third light emitting elements LD3 may be comprised in each of the series parts SP. For example, the third sub-pixel SPX3 may comprise first to b-th series parts SP1, SP2, . . . , and SPb electrically connected in series to each other. For example, the third sub-pixel SPX3 may comprise b series parts SP. The series parts SP of the third sub-pixel SPX3 may be electrically connected to the second power line PL2 and the third pixel circuit PXC3 that is electrically connected to the first power line PL1.

In an embodiment, the number of series parts SP for the first sub-pixel SPX1 configured to provide red light may be greater than the number of series parts SP for each of the second sub-pixel SPX2 and the third sub-pixel SPX3. For instance, r may be greater than g, and r maybe greater than b.

As described above, the emission efficiency (for example, internal quantum efficiency) of the light emitting element LD configured to emit red light may be less than the emission efficiency (for example, internal quantum efficiency) of the light emitting element LD configured to emit blue light or green light. In an embodiment, the number of series parts SP formed in the first sub-pixel SPX1 for red light may be greater than the number of series parts SP formed in each of the other sub-pixels SPX2 and SPX3, so that a deviation in emission efficiency depending on the color of emitted light may be compensated for, whereby the sub-pixels SPX may provide light having uniform luminance.

Furthermore, in an embodiment, taking into account external quantum efficiency of the light emitting element LD, the first to third pixel circuits PXC1, PXC2, and PXC3 may provide different driving currents, so that the deviation in emission efficiency depending on the color of emitted light can be further reliably compensated for.

Referring to FIG. 17, the display device DD in accordance with an embodiment may comprise a structure in which the size of the light emitting element LD is changed by each of the sub-pixels SPX, as the structure configured to compensate for the emission efficiency depending on the color of light emitted from the light emitting element LD.

As described above, the emission efficiency (for example, the internal quantum efficiency) of the light emitting element LD may be reduced as the size of the light emitting element LD is reduced. Therefore, in accordance with an embodiment, the size of the first light emitting element LD1 configured to provide red light as a light emitting element LD having relatively low emission efficiency may be greater than the size of the second light emitting element LD2 configured to provide green light or the third light emitting element LD3 configured to provide blue light as a light emitting clement having relatively high emission efficiency.

The first light emitting element LD1 may have a first size L1 as a red light emitting element. In an embodiment, the active layer AL of the first light emitting element LD1 may have a first size L1. For example, the first size L1 may refer to the surface area of the active layer AL of the first light emitting element LD1. The second light emitting clement LD2 may have a second size L2 as a green light emitting element. In an embodiment, the active layer AL of the second light emitting element LD2 may have a second size L2. For example, the second size L2 may refer to the surface area of the active layer AL of the second light emitting element LD2. The third light emitting element LD3 may have a third size L3 as a red light emitting element. In an embodiment, the active layer AL of the third light emitting element LD3 may have a third size L3. For example, the third size L3 may refer to the surface area of the active layer AL of the third light emitting element LD3.

In an embodiment, the first size L1 may be greater than the second size L2. The first size L1 may be greater than the third size L3. In an embodiment, the first size L1 may be greater than the second size L2 or the third size L3. In other words, because the size of the first light emitting element LD1 configured to emit red light is greater than the size of each of the light emitting elements LD2 and LD3 configured to emit other colors of light, the first to third light emitting elements LD1, LD2, and LD3 in the respective sub-pixels SPX may have substantially uniform emission efficiency. Consequently, a deviation in emission efficiency depending on the color of emitted light may be compensated for, so that the sub-pixels SPX may provide light having substantially uniform luminance.

Depending on the embodiment, the display device DD may comprise, as the structure for compensating for the emission efficiency depending on the color of light emitted from the light emitting element LD, both the structure in which the sub-pixels SPX are designed to be different from each other in the number of series parts SP as described with reference to FIG. 16, and the structure in which the size of the light emitting element LD is changed by each of the sub-pixels SPX.

Consequently, in the display device DD in accordance with an embodiment, the deviation in emission efficiency of the light emitting elements LD may be compensated for, so that the sub-pixels SPX may have uniform light output efficiency.

Various embodiments of the disclosure may provide a light emitting element having a reduced defect rate, a method of manufacturing the light emitting element, and a display device comprising the light emitting element.

Various embodiments of the disclosure may provide a light emitting element having improved emission efficiency, a method of manufacturing the light emitting element, and a display device comprising the light emitting element.

Various embodiments may provide a light emitting element, a method of manufacturing the light emitting element, and a device comprising the light emitting element, in which structures of sub-pixels having substantially uniform light efficiency can be implemented by compensating for emission efficiency by colors of light emitting elements.

While various embodiments have been described above, those skilled in the art will appreciate that various modifications, additions and substitutions are possible, without departing from the scope and spirit of the disclosure.

Therefore, the embodiments disclosed in this specification are only for illustrative purposes rather than limiting the technical spirit of the disclosure. The scope of the disclosure is defined by the accompanying claims.

What is claimed is:

1. A light emitting element comprising:
a semiconductor stack structure comprising:
an N-type semiconductor layer;
a P-type semiconductor layer; and
an active layer disposed between the N-type semiconductor layer and the P-type semiconductor layer;
an intermediate passivation structure disposed on a side surface of the semiconductor stack structure; and
an insulating layer disposed on the intermediate passivation structure, and comprising a metal oxide,
wherein the intermediate passivation structure comprises a crystal structure comprising nitrogen (N), and a material forming the semiconductor stack structure.

2. The light emitting element according to claim 1, wherein
the semiconductor stack structure comprises GaP, and
the intermediate passivation structure comprises GaPₓN₍₁₋ₓ₎.

3. The light emitting element according to claim 1, wherein
the semiconductor stack structure comprises InₓAl_{y}Ga_{(1-x-y)}P, and
the intermediate passivation structure comprises AlₓIn_{y}Ga_{(1-y)}PzN_{(1-z)}.

4. The light emitting element according to claim 1, wherein
the intermediate passivation structure spaces apart an interior of the semiconductor stack structure from the insulating layer, and
the insulating layer comprises a metal oxide comprising at least one metal selected from a group comprising tantalum (Ta), hafnium (Hf), zirconium (Zr), lanthanum (La), silicon (Si), titanium (Ti), and aluminum (Al).

5. The light emitting element according to claim 1, wherein the insulating layer comprises insulating layers comprising two or more materials different from each other.

6. The light emitting element according to claim 1, wherein the metal oxide forming the insulating layer has a bonding energy greater than a bonding energy of the material forming the semiconductor stack structure.

7. The light emitting element according to claim 2, wherein
in a crystal structure of the intermediate passivation structure comprising the GaP, a displacement of P based on a reference position is determined to be within about 8% compared to a bonding length between Ga and P, and
the reference position of the P is a position of the P in the crystal structure of the intermediate passivation structure in case that a separate energy is not supplied to the light emitting element.

8. The light emitting element according to claim 1, wherein a diameter of the light emitting element is about 100 μm or less.

9. The light emitting element according to claim 1, wherein
the intermediate passivation structure is an intermediate passivation layer, and
a first surface of the intermediate passivation layer contacts the semiconductor stack structure, and a second surface of the intermediate passivation layer contacts the insulating layer.

10. The light emitting element according to claim 1, wherein
the intermediate passivation structure comprises an intermediate passivation area, and
the intermediate passivation area comprises an area in which a side surface of the semiconductor stack structure is doped with N.

11. The light emitting element according to claim 1, wherein the light emitting element comprises a red light emitting element that emits red light.

12. A display device, comprising the light emitting element according to claim 1, that allows the light emitting element to be supplied with an energy of about 0.15 eV or less in case that the light emitting element emits light.

13. A method of manufacturing a light emitting element, comprising:
patterning a semiconductor stack structure on a growth substrate;
forming an intermediate passivation structure on a side surface of the semiconductor stack structure; and
forming an insulating layer comprising a metal oxide on the intermediate passivation structure, wherein the semiconductor stack structure comprises GaP, and the intermediate passivation structure comprises GaPₓN₍₁₋ₓ₎.

14. The method according to claim 13, wherein the forming of the intermediate passivation structure comprises forming an intermediate passivation layer comprising GaPₓN₍₁₋ₓ₎ on the side surface of the semiconductor stack structure.

15. The method according to claim 13, wherein the forming of the intermediate passivation structure comprises doping the side surface of the semiconductor stack structure with nitrogen (N).

16. The method according to claim 13, wherein the insulating layer comprises a metal oxide comprising at least one metal selected from a group comprising tantalum (Ta), hafnium (Hf), zirconium (Zr), lanthanum (La), silicon (Si), titanium (Ti), and aluminum (Al).

17. The method according to claim 13, further comprising:
separating a structure comprising the semiconductor stack structure, the intermediate passivation structure, and the insulating layer.

18. The method according to claim 13, wherein the patterning of the semiconductor stack structure comprises sequentially growing semiconductor layers on the growth substrate;
and etching the grown semiconductor layers.

19. A display device, comprising:
a base layer; and
sub-pixels disposed on the base layer, wherein
each of the sub-pixels comprises series parts comprising light emitting elements, an anode connection electrode electrically connected to the series parts, and a cathode connection electrode electrically connected to the series parts,
the sub-pixels comprise a first sub-pixel that provides red light, a second sub-pixel that provides green light, and a third sub-pixel that provides blue light,
the light emitting elements comprise first light emitting elements comprised in the first sub-pixel, second light emitting elements comprised in the second sub-pixel, and third light emitting elements comprised in the third sub-pixel,
the series parts comprise r red series parts comprised in the first sub-pixel, g green series parts comprised in the second sub-pixel, and b blue series parts comprised in the third sub-pixel,
r, g, and b are natural numbers, and
r is greater than g or b.

20. A display device, comprising:
a base layer; and
sub-pixels disposed on the base layer, and comprising a first sub-pixel comprising a first light emitting element that emits red light, a second sub-pixel comprising a second light emitting element that emits green light, and a third sub-pixel comprising a third light emitting element that emits blue light, wherein
the first light emitting element has a first size,
the second light emitting element has a second size,
the third light emitting clement has a third size, and
the first size is greater than the second size or the third size.
